(19) United States
(12) Patent Application Publication
(10) Pub. No.: US 2011/0058584 A1
(43) Pub. Date: Mar. 10, 2011

(54) SEMICONDUCTOR LASER DEVICE AND FABRICATION METHOD FOR THE SAME

(76) Inventors: Hiroshi Ohno, Hyogo (JP); Yoshiaki Hasegawa, Okayama (JP); Katsumi Sugiura, Hyogo (JP)

(21) Appl. No.: 12/312,150

(22) PCT Filed: Nov. 12, 2008
(86) PCT No.: PCT/JP2008/003286

§ 371 Date: Apr. 28, 2009

(30) Foreign Application Priority Data
Nov. 19, 2007 (JP) 2007-299573

(51) Int. Cl. H01S 5/22; H01L 21/30

(52) U.S. Cl. 372/45.01; 438/31; 257/E21.211

(57) ABSTRACT

A semiconductor laser device includes a semiconductor multilayer structure 12 having a stripe-shaped ridge waveguide portion 12a extending in a direction intersecting a cavity end face. A dielectric layer 16 is formed on the semiconductor multilayer structure 12 to cover at least part of both side faces of the ridge waveguide portion 12a. Light absorption layers 17 are formed on both sides of the ridge waveguide portion 12a on the semiconductor multilayer structure 12 so as to be spaced from the ridge waveguide portion 12a and the cavity end face.

### TECHNICAL FIELD

The present invention relates to a semiconductor laser device and a fabrication method for the same, and more particularly to a blue to ultraviolet semiconductor laser device using a nitride and the fabrication method for the same.

### BACKGROUND ART

Conventionally, III-V compound semiconductor laser devices, such as aluminum gallium arsenic (AlGaAs) infrared lasers and indium gallium phosphorus (InGaP) red lasers, have been widely used as lasers for communication and as read and write elements for compact discs (CDs) and digital versatile discs (DVDs).

In recent years, blue and ultraviolet semiconductor laser devices having a shorter wavelength have been implemented using nitride semiconductors represented by a general formula AlₓGa_{y}In_{(1-x-y)}N (0≦x≦1, 0≦y≦1, 0≦1−x−y≦1). Such semiconductor laser devices have been increasing put in practical use as light sources for read and write of high-density optical discs such as next-generation DVDs (Blu-Ray Discs). At present, as blue semiconductor laser devices, low-power ones of several tens of mW for playback and high-power ones of 100 mW class for recording are commercially available. To improve the recording speed, further increase in the power of blue semiconductor laser devices has been attempted; even 200 mW-class semiconductor laser devices are now coming on the market.

In general, in a nitride semiconductor laser device, narrowing of an injected current in a direction horizontal to the substrate is performed with a ridge structure formed by etching part of a nitride semiconductor material into a stripe shape. Also, light trapping in a direction horizontal to the substrate is performed with a real index guided structure. Hence, laser light propagating inside a stripe-shaped light waveguide region is likely to leak in a substrate horizontal direction. Leak light (stray light) is subjected to multiple reflection in a laser cavity direction and finally released from the output end face. As a result, stray light interferes with a principal laser beam, resulting in appearance of ripples in a far field pattern (FFP) and deviation from a Gaussian shape. If such a laser beam is used for read and write of an optical disc, the light use efficiency decreases, resulting in occurrence of noise and occurrence of a readout error.

Methods for suppressing ripples caused by leak light in a substrate horizontal direction to obtain a good FFP shape have been so far examined.

For example, disclosed is a method in which a p-side electrode is also formed consecutively on a portion outside a ridge stripe where a p-type cladding layer is exposed (see Patent Document 1, for example). Stray light leaking outside the ridge waveguide portion is therefore absorbed with the p-side electrode, and hence the FFP shape can be improved.

Also disclosed is a technique in which a light absorption region made of a dielectric, a metal or a semiconductor having a refractive index larger than that of a waveguide is formed in a portion apart from the ridge waveguide portion, to thereby improve the FFP shape (see Patent Documents 2 and 3, for example).

Yet another technique disclosed is forming a plurality of concave portions near the light output end face to scatter leak light from the ridge waveguide portion, to thereby improve the FFP shape (see Patent Document 4, for example).

### Patent Document 1: Japanese Laid-Open Patent Publication No. 11-186650

### Patent Document 2: Japanese Laid-Open Patent Publication No. 2002-237661

### Patent Document 3: Japanese Laid-Open Patent Publication No. 2006-216731

### Patent Document 4: Japanese Laid-Open Patent Publication No. 2005-311308

### DISCLOSURE OF THE INVENTION

### Problems to be Solved by the Invention

However, the conventional techniques for improving the FFP shape have the following problems. In the case of forming the p-side electrode, not only on the ridge waveguide portion, but also on the exposed face of the p-type cladding layer, a current may also flow in a portion other than the ridge waveguide portion. The current flowing in a portion other than the ridge waveguide portion is merely about a millionth of that flowing in the ridge waveguide portion. However, if the injected current is increased to increase the power of the semiconductor laser, the leak current flowing in a portion other than the ridge waveguide will be no more negligible. The leak current will worsen the FFP shape and cause new ripples.

To form the p-side electrode also in a portion other than the ridge waveguide portion, the width of the p-side electrode must be far greater than the width of the ridge waveguide portion. Such a wide p-side electrode will cause a cleavage failure with which a crack, a minute step and chip and the like may occur at the cavity end face portions. Also, electrode coming-off is likely to occur at the end face portions. As a result, the yield will decrease. Moreover, light is likely to scatter at the end face portions, and this will become a new cause for a faulty FFP shape.

No leak current will occur if an absorption layer made of a dielectric is formed. However, with no dielectric material having a sufficiently large absorption coefficient existing, a sufficient light absorption effect is unavailable.

If the absorption layer is made of a semiconductor, at least two times of growth of a semiconductor layer is necessary, and this is very disadvantageous in terms of cost. Also, a semiconductor layer active in light absorption tends to be a layer having many defects, a layer rich in impurity, a layer high in In content or the like. Hence, such an absorption layer will facilitate deterioration of the semiconductor laser device, degrading the reliability.

In the case of forming concave portions to scatter leak light without forming an absorption layer, the above problems relating to the absorption layer do not occur. However, since the leak light is merely scattered, part of the scattered light returns to the waveguide portion as light of a different phase, causing noise. In a nitride semiconductor laser device, there arise band bending due to spontaneous polarization and a piezoelectric effect caused by strain, band shrinkage due to high injection carrier density, a red shift of the oscillation wavelength due to heat generation and the like. For this reason, the oscillation wavelength in the ridge waveguide portion tends to be longer than the wavelength at an absorption edge in the surrounding region. Hence, by merely scattering leak light from the waveguide, light cannot be absorbed but is repeatedly scattered inside the cavity as stray light. Finally, such light leaks out from an end face, possibly interfering with the FFP or returning to inside the waveguide region causing noise.

An object of the present invention is implementing a nitride semiconductor laser device in which ripples are reduced and the far field pattern shape is close to a Gaussian shape.

### Means for Solving the Problems

To attain the above object, according to the present invention, the semiconductor laser device is configured to include light absorption layers formed on both sides of a ridge waveguide portion.

The semiconductor laser device of the present invention is directed to a semiconductor laser device provided with a cavity structure having a pair of cavity end faces opposed to each other, including: a semiconductor multilayer structure including an n-type semiconductor layer, an active layer and a p-type semiconductor layer sequentially formed on a substrate in this order and having a stripe-shaped ridge waveguide portion extending in a direction intersecting the cavity end faces; a dielectric layer formed on the semiconductor multilayer structure to cover at least part of both side faces of the ridge waveguide portion; light absorption layers formed on both sides of the ridge waveguide portion on the semiconductor multilayer structure so as to be spaced from the ridge waveguide portion and the cavity end faces; and a p-side electrode formed on the ridge waveguide portion.

The semiconductor laser device of the present invention includes light absorption layers formed on both sides of the ridge waveguide portion on the semiconductor multilayer structure so as to be spaced from the ridge waveguide portion and the cavity end faces. With this configuration, the intensity of leak light leaking sideways from the ridge waveguide portion can be reduced. Hence, the far field pattern shape of light emerging from the semiconductor laser device can be improved. Also, being spaced from the cavity end faces, the light absorption layers will not obstruct cleavage.

In the semiconductor laser device of the invention, the light absorption layers are preferably conductive and electrically insulated from the p-side electrode. With this configuration, even when the light absorption layers are made of a conductive material, the leak current from the light absorption layer can be made null. Hence, a material such as a metal high in effective absorption coefficient can be used without causing stray light due to a leak current or degrading the reliability.

The semiconductor laser device of the invention may further include an insulating layer formed between the light absorption layers and the p-side electrode. With this configuration, the length of the optical absorption layers in the cavity direction can be increased.

In the semiconductor laser device of the invention, the light absorption layers may be axially symmetric with respect to the ridge waveguide portion.

In the semiconductor laser device of the invention, the light absorption layers may be formed near a light output end face, out of the cavity end faces, from which light emerges. With this configuration, the light absorption layers and the p-side electrode can be insulated from each other without forming an insulating film.

In the semiconductor laser device of the invention, each of the light absorption layers may have a first portion formed near a light output end face from which light emerges and a second portion formed near a cavity end face opposite to the light output end face. With this configuration, the length of the light absorption layers in the cavity direction can be increased.

In the semiconductor laser device of the invention, the spacing between the first portion and the light output end face may be equal to the spacing between the second portion and the cavity end face opposite to the light output end face. In this case, the first portion and the second portion may be axially symmetric with respect to a center line of the cavity structure in an end face direction.

In the semiconductor laser device of the invention, the semiconductor multilayer structure may have a step portion formed at least at a region of the cavity end faces excluding the ridge waveguide portion. With this configuration, correct cleavage can be made at the time of cleavage of the semiconductor laser device.

In the semiconductor laser device of the invention, the distance between the light absorption layers and the center of the ridge waveguide portion may be 10 μm or less.

In the semiconductor laser device of the invention, the length of the light absorption layers in a direction parallel to the ridge waveguide portion may be 5 μm or more.

In the semiconductor laser device of the invention, the light absorption layers may be made of a material whose refractive index n and extinction coefficient k at an oscillating wavelength satisfy n≧1 and n+2k≧2. In this case, it may be made of a material whose refractive index n and extinction coefficient k at an oscillating wavelength satisfy n>2 and 0.001<k<2.5.

In the semiconductor laser device of the invention, the light absorption layers may be made of a material whose extinction coefficient at an oscillating frequency is 1 or more.

In the semiconductor laser device of the invention, the light absorption layers may include at least one of Cu, Pd, Zr, Nb, Cr, Ni, Au, Pt, Ti, Ta, W, Mo and amorphous Si.

In the semiconductor laser device of the invention, the light absorption layers may include at least one of CrN, TiN, ZrN, NbN, TaN and MoN.

In the semiconductor laser device of the invention, the light absorption layers may include the same metal material as that included in the p-side electrode.

The fabrication method for a semiconductor laser device of the present invention includes the steps of: forming a semiconductor multilayer structure including an n-type semiconductor layer, an active layer and a p-type semiconductor layer on a substrate sequentially by crystal growth; forming a ridge waveguide portion extending in a cavity direction in the p-type semiconductor layer; forming a dielectric layer on the p-type semiconductor layer; forming a first opening exposing the top face of the ridge waveguide portion in the dielectric layer and also forming a second opening exposing the p-type semiconductor layer in at least part of a region of the dielectric layer excluding the ridge waveguide portion and a portion becoming a cavity end face by cleavage; and forming a p-side electrode and a light absorption layer by filling the first opening and the second opening with a metal material.

The fabrication method for a semiconductor laser device of the present invention includes a step of forming a p-side electrode and a light absorption layer by filling the first opening and the second opening with a metal material. Hence, since the p-side electrode and the light absorption layer can be formed simultaneously, the number of process steps can be reduced.

### EFFECT OF THE INVENTION

According to the semiconductor laser and the fabrication method for the same of the present invention, a nitride semiconductor laser device in which ripples are reduced and the far field pattern shape is close to a Gaussian shape can be implemented.

### BRIEF DESCRIPTION OF THE DRAWINGS

FIGS. 1(a) to 1(d) show a semiconductor laser device of Embodiment 1 of the present invention, wherein (a) is a plan view, (b) is a cross-sectional view taken along line Ib-Ib in (a), (c) is a cross-sectional view taken along line Ic-Ic in (a), and (d) is a cross-sectional view taken along line Id-Id in (a).

FIG. 2 is an enlarged plan view of a light absorption layer of the semiconductor laser device of Embodiment 1 of the present invention.

FIGS. 3(a) and 3(b) show characteristics of a semiconductor laser device provided with no light absorption layer, wherein (a) shows the measurement results of a horizontal far field pattern, and (b) shows the simulation results of a near field pattern obtained from the horizontal far field pattern.

FIG. 4 is a graph showing the relationship between the length of the light absorption layer in the cavity direction and the leak light absorptance thereof.

FIG. 5 is a graph showing the relationship between the effective absorptance of the light absorption layer and the length thereof in the cavity direction.

FIG. 6 is a graph showing the results of calculation of the effective absorptance of the light absorption layer based on the refractive index and the extinction coefficient.

FIG. 7 is a table of the refractive index and the extinction coefficient of various materials.

FIGS. 8(a) and 8(b) show characteristics of the semiconductor laser device of Embodiment 1 of the present invention, wherein (a) shows the measurement results of a horizontal far field pattern, and (b) shows the simulation results of a near field pattern obtained from the horizontal far field pattern.

FIGS. 9(a) to 9(c) are plan views showing alterations of the light absorption layer of the semiconductor laser device of Embodiment 1 of the present invention.

FIGS. 10(a) to 10(d) show a semiconductor laser device of Embodiment 2 of the present invention, wherein (a) is a plan view, (b) is a cross-sectional view taken along line Xb-Xb in (a), (c) is a cross-sectional view taken along line Xc-Xc in (a), and (d) is a cross-sectional view taken along line Xd-Xd in (a).

FIG. 11 is a plan view showing a state of the semiconductor laser device of Embodiment 2 of the present invention before primary cleavage.

FIG. 12 is a plan view showing a state of an alteration of the semiconductor laser device of Embodiment 2 of the present invention before primary cleavage.

FIGS. 13(a) and 13(b) show the alteration of the semiconductor laser device of Embodiment 2 of the present invention, wherein (a) is a plan view and (b) is a cross-sectional view at a cavity end face.

FIGS. 14(a) to 14(d) show a semiconductor laser device of Embodiment 3 of the present invention, wherein (a) is a plan view, (b) is a cross-sectional view taken along line XIVb-XIVb in (a), (c) is a cross-sectional view taken along line XIVc-XIVc in (a), and (d) is a cross-sectional view taken along line XIVd-XIVd in (a).

FIGS. 15(a) to 15(d) show a semiconductor laser device of Embodiment 4 of the present invention, wherein (a) is a plan view, (b) is a cross-sectional view taken along line XVb-XVb in (a), (c) is a cross-sectional view taken along line XVc-XVc in (a), and (d) is a cross-sectional view taken along line XVd-XVd in (a).

### DESCRIPTION OF REFERENCE NUMERALS

10 Substrate
12 Semiconductor multilayer structure
12A Light output end face
12B Rear end face
12a Ridge waveguide portion
13 N-type semiconductor layer
14 Active layer
15 P-type semiconductor layer
16 Dielectric layer
17 Light absorption layer
17A First portion
17B Second portion
18 Insulating layer
21 P-side electrode
22 N-side electrode
23 P-side electrode pad
31 N-type GaN layer
32 N-type cladding layer
33 N-type guide layer
51 Optical guide layer
52 P-type cladding layer
53 P-type contact layer
61 Primary cleavage line
62 Cleavage guide groove
62a Step portion

### BEST MODE FOR CARRYING OUT THE INVENTION

It is known that in a ridge waveguide-type semiconductor laser device, a near field pattern (NFP) is worsened with leak light from the ridge waveguide portion. The inventors of the present invention have first made in-depth examination on how leak light from a ridge waveguide portion occurs. As a result, it has been found that leak light occurs because light propagating inside the ridge waveguide portion is scattered due to minute fluctuation of the ridge waveguide portion and the morphology of the surface of a semiconductor layer. Also found has been that as the ridge is narrower, the effect of the scattering is larger and hence leak light increases.

Leak light exists on both sides of the ridge waveguide portion in the NFP. It has been found that when the relative intensity of leak light standardized with respect to the peak intensity of the NFP becomes about 1×10⁻³, ripples significantly appear in the far field pattern (FFP). Conversely, it has also been found that when the relative intensity of leak light is 5×10⁻⁴ or less, ripples in the FFP considerably decreases, and that when the relative intensity is 1×10⁻⁴ or less, no ripple is observed at all in the FFP, permitting attainment of a good FFP shape.

The ridge width of a nitride semiconductor laser device is comparatively small, which is generally about 1 μm to 2 μm. Hence, a nitride semiconductor laser device tends to cause leak light. By increasing the ridge width, improvement in FFP shape is expected. However, an increased ridge width may possibly worsen other characteristics such as the threshold current, kinking and the angle of divergence. Changing of the ridge width is therefore not easy. Also, in a nitride semiconductor laser device, there arise phenomena such as band bending due to spontaneous polarization and the piezoelectric effect caused by strain, band shrinkage due to high injection carrier density and a red shift of the oscillation wavelength due to heat generation. For this reason, the oscillation wavelength in the ridge waveguide portion is often longer than the wavelength at an absorption edge in the surrounding region. Hence, light that has leaked from the ridge waveguide portion becomes stray light propagating outside the ridge waveguide portion without being absorbed. Such stray light finally emerges from the light output end face, appearing as ripples in the FFP shape.

As described above, in a nitride semiconductor laser device, it is structurally difficult to prevent occurrence of leak light. Hence, for improving the NFP and the FFP, it is necessary to prevent leak light from being released from the light output end face in one way or another. The present inventors have found as a result of examination that leak light can be effectively absorbed by forming a light absorption layer made of a material large in light absorption property on a semiconductor layer in a region other than the ridge waveguide portion.

Leak light from the ridge waveguide portion may occur roughly symmetrically with respect to the ridge waveguide portion. Hence, it is considered effective to form light absorption layers on both sides of the ridge waveguide portion symmetrically.

Also, it has been found most effective to form light absorption layers near the light output end face. The reasons for this seem to be that leak light mainly propagates in the cavity direction and is finally released from the light output end face and that the light density distribution in the cavity direction is highest near the light output end face.

Hereinafter, a semiconductor laser device improved in FFP shape implemented based on the examination results described above will be described in concrete ways.

### Embodiment 1

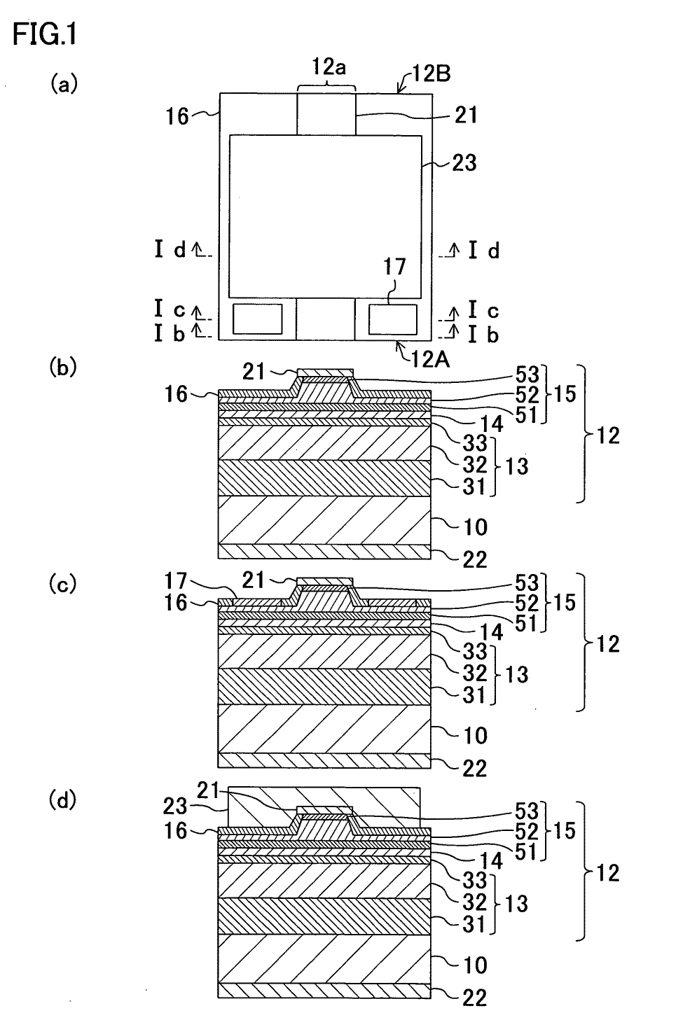

Embodiment 1 of the present invention will be described with reference to the relevant drawings. FIGS. 1(a) to 1(d) show a semiconductor laser device of Embodiment 1, wherein (a) shows a plan structure, and (b), (c) and (d) respectively show cross-sectional structures taken along line Ib-Ib, line Ic-Ic and line Id-Id in (a).

The semiconductor laser device of this embodiment, formed by cleavage, is provided with a cavity structure having a pair of cavity end faces opposed to each other. The cavity structure, formed on a substrate, is composed of a semiconductor multilayer structure 12 having a stripe-shaped ridge waveguide portion 12a extending in the cavity direction and multilayer dielectric reflection films formed on the cavity end faces. The semiconductor laser device of this embodiment is also provided with light absorption layers 17 formed on both sides of the ridge waveguide portion 12a on the semiconductor multilayer structure 12. With this placement, leak light from the ridge waveguide portion 12a can be absorbed, permitting improvement of the FFP shape.

Specifically, the semiconductor multilayer structure 12 has an n-type semiconductor layer 13, an active layer 14 and a p-type semiconductor layer 15 formed sequentially on a substrate 10 made of n-type GaN. The semiconductor multilayer structure 12 can be in any form as long as a laser cavity can be formed. For example, it may be configured as follows.

The n-type semiconductor layer 13 includes an n-type GaN layer 31 having a thickness of 1 μm, an n-type cladding layer 32 made of n-Al_{0.04}Ga_{0.96}N having a thickness of 2.5 μm and an n-type guide layer 33 made of n-type GaN (n-GaN) having a thickness of 150 nm. The active layer 14 is of a triple quantum well structure including well layers made of In_{0.10}Ga_{0.90}N having a thickness of 3 nm and barrier layers made of In_{0.02}Ga_{0.98}N having a thickness of 7.5 nm. The p-type semiconductor layer 15 includes a p-type optical guide layer 51 made of p-type GaN (p-GaN) having a thickness of 120 nm, a p-type cladding layer 52 made of p-Al_{0.05}Ga_{0.95}N having a thickness of 0.5 μm and a p-type contact layer 53 made of p-GaN having a thickness of 100 nm.

A buffer layer may be formed between the semiconductor multilayer structure 12 and the substrate 10. The buffer layer may be made of n-GaN having a thickness of 200 nm, for example. The semiconductor multilayer structure 12 may be formed by metal-organic chemical vapor deposition (MOCVD) or the like. In formation of an n-type layer, silicon (Si) may be doped as a donor impurity at a density of about 5×10¹⁷ cm⁻³. In formation of a p-type layer, magnesium (Mg) may be doped as an acceptor impurity at a density of about 1×10²⁰ cm⁻³.

The ridge waveguide portion 12a extending in the cavity direction is formed in the semiconductor multilayer structure 12. The ridge waveguide portion 12a may be formed by selectively removing part of the p-type cladding layer 52 and the p-type contact layer 53. A dielectric layer 16 made of silicon dioxide (SiO₂) having a thickness of 200 nm is formed on the side faces of the ridge waveguide portion 12a and on the p-type cladding layer 52 excluding the portion constituting the ridge waveguide portion 12a. Note that the dielectric layer 16 does not necessarily cover the entire side faces of the ridge waveguide portion 12a but may just cover at least part thereof.

The dielectric layer 16 has openings for exposing the p-type cladding layer 52 at predetermined positions on both sides of the ridge waveguide portion 12a, and the openings are filled with amorphous silicon forming the light absorption layers 17. The position, size, material and the like of the light absorption layers 17 will be described later in detail.

A p-side electrode 21 is formed on the ridge waveguide portion 12a via the p-type contact layer 53. An n-side electrode 22 is formed on the face (back face) of the substrate 10 opposite to the face on which the semiconductor multilayer structure 12 is formed. A p-side electrode pad 23 is formed on the dielectric layer 16 so as to cover the ridge waveguide portion 12a and is electrically connected with the p-side electrode 21.

The p-side electrode 21 may be a multilayer film of palladium (Pd) and platinum (Pt), for example. In formation of the p-side electrode 21, it is preferred to subject the substrate to electron beam evaporation while being overheated to 70° C. to 100° C. and thereafter to heat treatment at about 400° C. With this formation, the contact resistance of the p-side electrode 21 can be reduced and also the cohesion thereof can be improved. The p-side electrode pad 23 and the n-side electrode 22 may be a multilayer film of titanium (Ti), platinum (Pt) and gold (Au).

The p-side electrode pad 23 is formed to be spaced from the light absorption layers 17, so that the p-side electrode 21 and the light absorption layers 17 are electrically insulated from each other. Hence, no leak current will flow to the semiconductor multilayer structure 12 via the light absorption layers 17 that are in contact with the p-type cladding layer 52.

A multilayer dielectric reflection film (not shown) having a reflectance of 50% is formed on a light output end face 12A from which laser light in the semiconductor multilayer structure 12 emerges, and a multilayer dielectric reflection film (not shown) having a reflectance of 95% is formed on a rear end face 12B opposite to the light output end face 12A. The semiconductor multilayer structure 12 thus functions as a laser cavity.

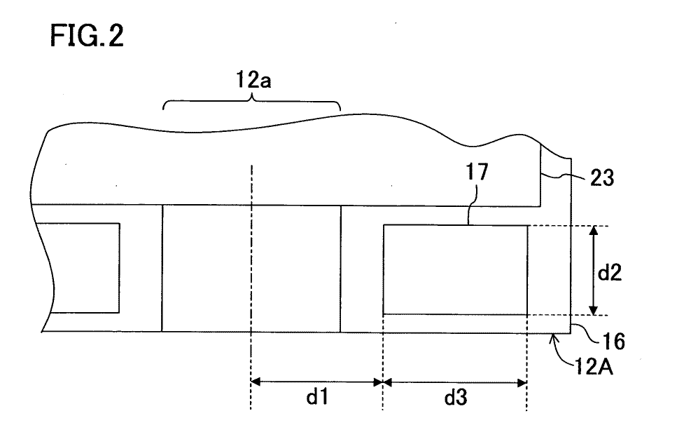

Hereinafter, the formation position and size of the light absorption layers 17 will be described in more detail. FIG. 2 shows the planar positional relationship between the light absorption layer 17 and the ridge waveguide portion 12a. From the viewpoint of absorbing leak light from the ridge waveguide portion 12a, the light absorption layer 17 should be formed on the entire surface of the p-type cladding layer excluding the portion constituting the ridge waveguide portion 12a. However, various restrictions are imposed on the region in which the light absorption layer 17 is formed.

It is theoretically considered most effective to form the light absorption layer 17 in contact with the light output end face 12A. However, if the light absorption layer 17 is formed over a cleavage line before the cleavage process into elements, it may obstruct the cleavage causing a crack and a step at the cleavage end face and thus degrading the effect of improving the FFP shape. The light absorption layer 17 must be made of a material excellent in light absorption property. Hence, a metal material is preferably used as will be described later. A metal layer formed by general evaporation, which is rich in amorphous ingredients, has spreading nature and lacks in cleavage nature. Therefore, if a metal layer is formed over a cleavage portion of an element, it will obstruct the cleavage; a crack and a step may occur at the cleavage end face, or only the metal layer may be divided at a position deviated from the cleavage line. As a result, the FFP shape may be worsened instead of being improved. In view of the above, the light absorption layer 17 must be formed to be spaced from the light output end face.

Also, if the light absorption layer 17 and the ridge waveguide portion 12a are in contact with each other, the principal beam propagating inside the ridge waveguide portion 12a will be absorbed by the light absorption layer 17. For this reason, the light absorption layer 17 must be spaced from the ridge waveguide portion 12a. However, if the light absorption layer 17 is excessively apart from the ridge waveguide portion 12a, it may possibly fail to absorb leak light that affects the FFP shape.

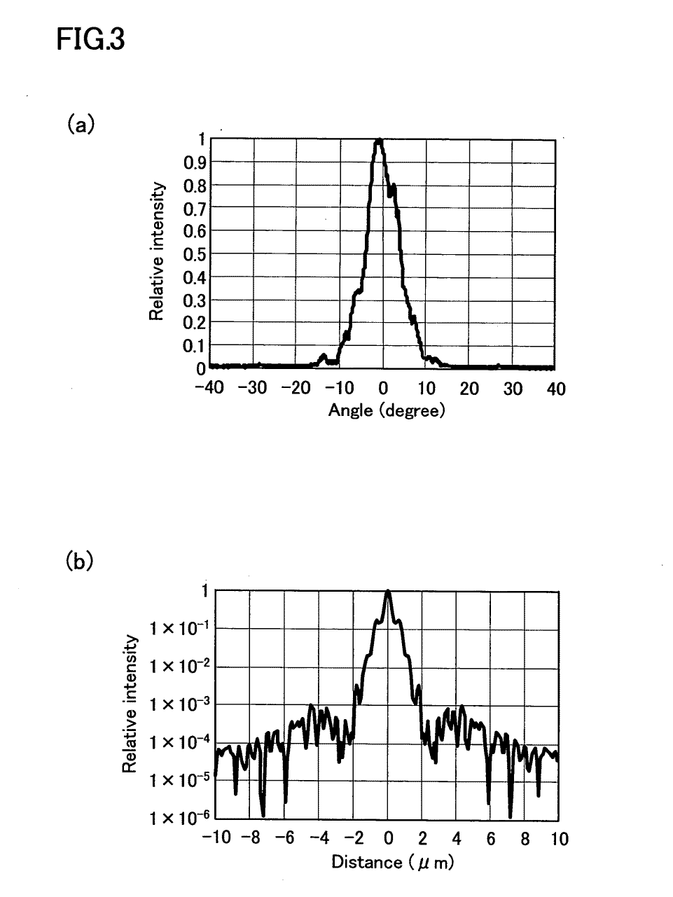

FIGS. 3(a) and 3(b) respectively show the intensity distribution of a horizontal FFP obtained from a conventional semiconductor laser device having a width of a ridge waveguide portion of 1 μm and the intensity distribution of a NFP estimated from the intensity distribution of the horizontal FFP. The NFP estimation was made by executing inverse Fourier transformation for the FFP distribution. A correct NFP intensity distribution is unavailable from the FFP intensity distribution because light phase information has disappeared. In other words, the axial asymmetry of the NFP distribution cannot be estimated because no phase information is available. However, it has been confirmed that from comparison with the NFP observation results, the position and relative intensity of the estimated NFP roughly agree with the observed ones.

As shown in FIG. 3(b), the principal beam propagates within the range of about 2 μm from the center of the ridge waveguide portion. It is therefore not preferred to set a distance d1 from the center of the ridge waveguide portion to the light absorption layer 17 shown in FIG. 2 at less than 2 μm. Also, as described earlier, the FFP shape is hardly affected by leak light when the relative intensity of the leak light is 1×10⁻⁴ or less. It is therefore preferred to set the distance d1 from the center of the ridge waveguide portion 12a to the light absorption layer 17 at 10 μm or less. Since leak light is considered highest in the range of about 2 μm to 10 μm from the center of the ridge waveguide portion, d1 is more preferably set at about 2 μm to 3 μm.

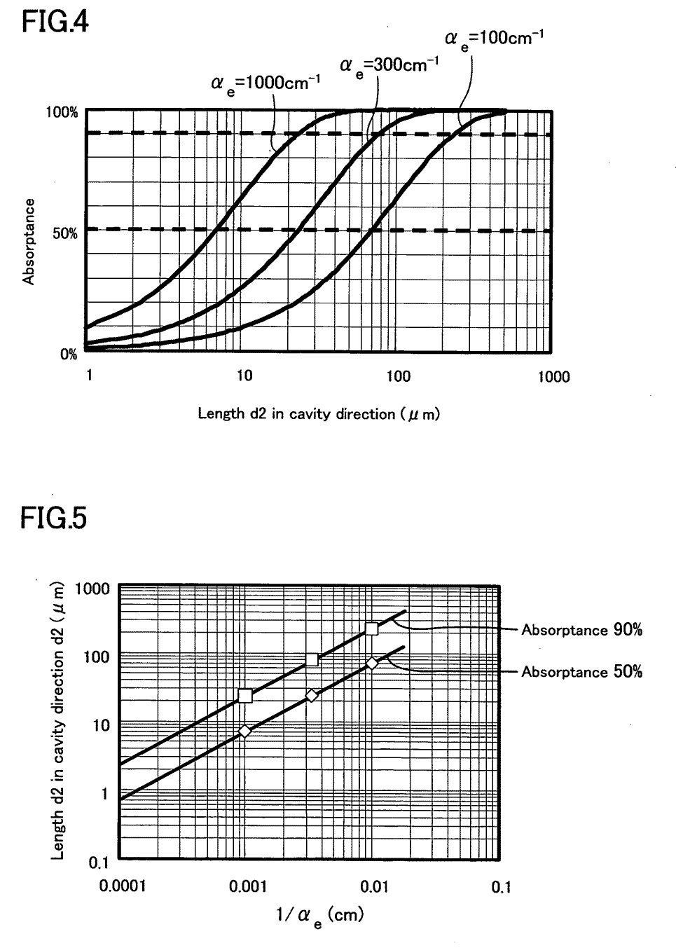

Next, a length d2 of the light absorption layer 17 in the cavity direction shown in FIG. 2 will be examined. The length d2 must be at least a length with which the leak light absorption effect is sufficiently exerted. FIG. 4 shows the relationship between the absorptance and d2 observed when the absorption coefficient of the light absorption layer 17 varies.

As shown in FIG. 4, when the effective absorption coefficient αe is 100 cm⁻¹, d2 must be about 70 μm for reducing leak light to ½, and about 250 μm for reducing leak light to 1/10. When the effective absorption coefficient αe is 1000 cm⁻¹, d2 must be about 7 μm for reducing leak light to ½, and about 25 μm for reducing leak light to 1/10. The effective absorption coefficient αe as used herein refers to the effective light absorption coefficient of the lower part of the light absorption layer 17 formed on the p-type cladding layer 52.

In reality, however, leak light propagating inside the cavity passes the region of the light absorption layer 17 a number of times while being reflected from the light output end face and the rear end face. When the reflectance of the light output end face is 50% and the reflectance of the rear end face is 95%, leak light is estimated to pass the region of the light absorption layer about three times on average. It is therefore considered possible to reduce leak light to ½ with d2 being only about 25 μm even when the effective absorption coefficient αe is 100 cm⁻¹. When the effective absorption coefficient αe is 1000 cm⁻¹, d2 can further be reduced.

FIG. 5 shows the relationship between d2 and the effective absorption coefficient ae in the cases of reducing leak light to ½ and 1/10. As is found from this graph, d2 and the inverse of the effective absorption coefficient αe are in a proportional relationship. Hence, the minimum value of d2 can be determined by

d2=c×(1/αe)

where c is a coefficient determined with the reduction rate of leak light. For example, the value of c will be about 7000 when leak light is reduced to ½, and about 23000 when leak light is reduced to 1/10. These are values obtained under the condition that the Al content in the p-type cladding layer in this embodiment is 3%. The value of c varies with the Al content in the p-type cladding layer 52 and the like; the value of c tends to be smaller as the Al content in the p-type cladding layer 52 is higher.

From the above, the length d2 of the light absorption layer 17 in the cavity direction, which must be changed with the material of the light absorption layer 17 and the required degree of reduction of leak light, is preferably about 2 μm to 50 μm.

The normal cavity length of a nitride semiconductor laser is about 400 μm to 800 μm. As long as the value of d2 is in the range of about 2 μm to 50 μm, the light absorption layer 17 can be spatially separated from the p-side electrode pad 23. Hence, even when the light absorption layer 17 is conductive, the light absorption layer 17 and the p-side electrode pad 23 can be isolated from each other without the necessity of providing an insulation film. As a result, the FFP shape can be improved in a simple process. Note that as long as the cavity length is long enough to permit the light absorption layer 17 to be spatially separated from the p-side electrode pad 23, d2 can be made further long without causing any trouble.

A width d3 of the light absorption layer 17 in the end face direction shown in FIG. 2 is preferably 10 μm or more, because with a width of about 10 μm, a major portion of the region in which leak light exists can be covered as shown in FIG. 3. Also, during secondary cleavage in the cavity direction, as during the primary cleavage, the cleavage precision will improve if the light absorption layer 17 has not been formed over a cleavage portion. Hence, the width d3 of the light absorption layer 17 in the end face direction is preferably set so that the light absorption layer 17 does not reach the side face of the cavity.

The material of the light absorption layer 17 will be described. As described earlier, the effective absorption coefficient αe of the lower part of the light absorption layer 17 is preferably 100 cm⁻¹ or more. The light absorption layer 17 is formed above the layer through which leak light propagates, and hence there is a spatial deviation from the light distribution of the leak light. The absorption effect thereof is therefore liable to be restrictive. However, the effective absorption coefficient αe of the light absorption layer can be roughly estimated from the refractive index n and extinction coefficient k of the light absorption layer and the material of the p-type cladding layer.

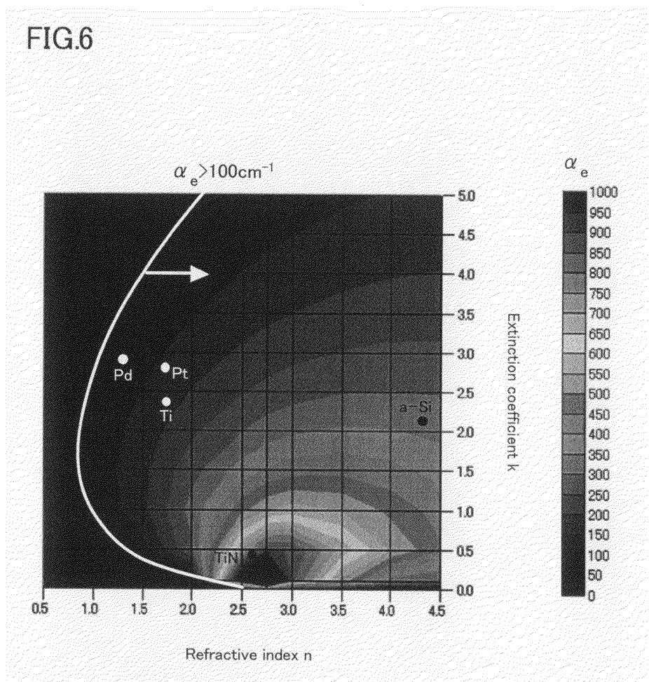

FIG. 6 shows the results of determination of the relationship among the refractive index n, the extinction coefficient k and the effective absorption coefficient αe at a wavelength of 405 nm. The effective absorption coefficient αe is an index representing the effective light absorption of lower part of the light absorption layer formed on the p-type cladding layer. This is therefore determined from the light absorption property of the light absorption layer, the difference in refractive index between the light absorption layer and the p-type cladding layer and the like. As shown in FIG. 6, to state broadly, the following materials can be used: a material having a refractive index n of about 2 or more and an extinction coefficient k of 0.001 or more and a material having a refractive index n of about 1 to 2 and an extinction coefficient k of about 1 to 4. More specifically, a material satisfying n≧1 and n+2k≧2 is preferable, and a material satisfying n>2 and 0.001<k<2.5 is more preferable. It is assumed in this case that the Al content in the p-type cladding layer is 3%. If the Al content is greater, the effective absorption coefficient ae tends to be greater.

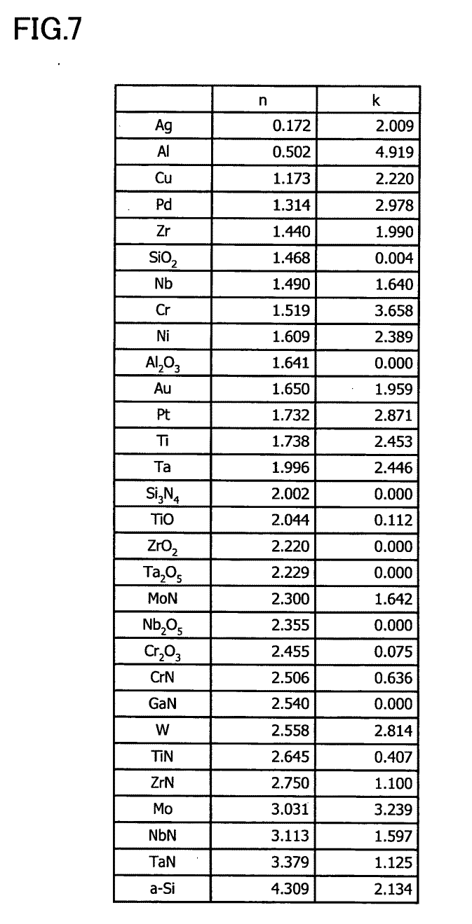

FIG. 7 shows the values of the refractive index n and extinction coefficient k of main materials. The following materials satisfying the conditions described above are preferably used: metal materials such as copper (Cu), palladium (Pd), zirconium (Zr), is niobium (Nb), chromium (Cr), nickel (Ni), gold (Au), platinum (Pt), titanium (Ti), tungsten (W), molybdenum (Mo) and tantalum (Ta); metal nitrides such as titanium nitride (TiN), chromium nitride (CrN), zirconium nitride (ZrN), niobium nitride (NbN), tantalum nitride (TaN) and molybdenum nitride (MoN); and amorphous silicon (a-Si). Multilayer films, alloys and the like of these materials may also be used. Materials such as silver (Ag) and aluminum (Al) falling outside the above range can also be used as long as the length d2 of the light absorption layer in the cavity direction can be made large.

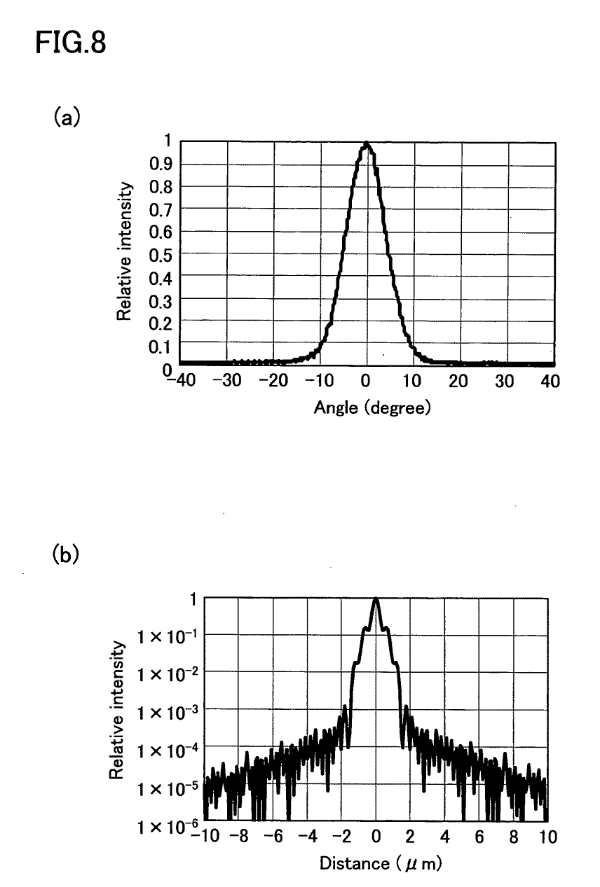

FIGS. 8(a) and 8(b) respectively show the intensity distribution of a horizontal FFP obtained from the semiconductor laser device of this embodiment and the intensity distribution of a NFP estimated from the FFP. FIG. 8 shows the measurement results obtained when the light absorption layer 17 is made of amorphous Si and has the distance d1 from the center of the ridge waveguide portion 12a of 2 μm, the length d2 in the cavity direction of 10 μm and the width d3 in the end face direction of 50 μm. Compared with the case shown in FIG. 3 provided with no light absorption layer, ripples are greatly reduced and a FFP shape close to a Gaussian shape is obtained.

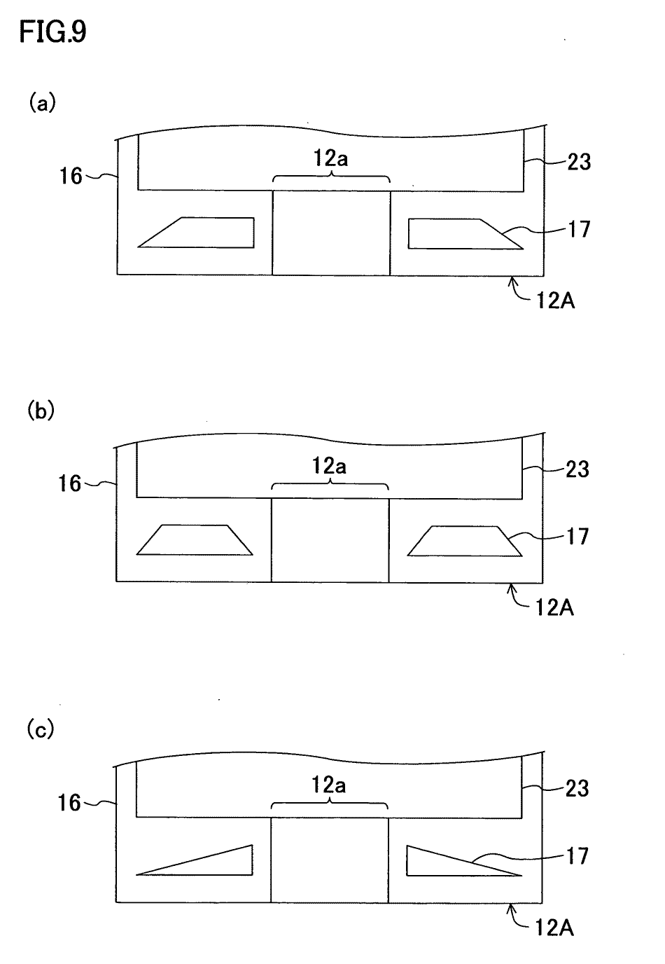

Although the shape of the light absorption layer 17 was a rectangle in plan, other shapes may also be adopted as shown in FIGS. 9(a) to 9(c). Considering the distribution of leak light and the light intensity distribution in the cavity direction, however, the shape is preferably such that the width in the end face direction is greater as the position is closer to the light output end face and that the length in the cavity direction is greater as the position is closer to the ridge waveguide portion.

The fabrication method for the semiconductor laser device of this embodiment is the same as that for normal semiconductor laser devices except for forming the light absorption layers 17. First, the semiconductor multilayer structure 12 is formed on the substrate 10 according to a normally-employed method. The p-type cladding layer 52 and the p-type contact layer 53 are then selectively etched to form the ridge waveguide portion 12a. The dielectric layer 16 is then formed on the semiconductor multilayer structure 12 including the ridge waveguide portion 12a, and a first opening exposing the top face of the ridge waveguide portion 12a is formed. The p-side electrode made of Pd and Pt is then formed in the first opening. Thereafter, second openings exposing the p-type cladding layer 52 are formed in predetermined regions of the dielectric layer 16. The formation of the second openings may be made by photolithography and with buffered hydrogen fluoride (BHF), for example. A material such as silicon or a metal is then evaporated to fill the second openings with the material to thereby form the light absorption layers 17. Thereafter, the p-side electrode pad is formed at a predetermined position. After thinning the substrate 10, the n-side electrode is formed on the back face of the substrate. Primary cleavage is then performed through breaking from the back face of the substrate to form cavity end faces, and multilayer dielectric reflection films are formed on the cavity end faces. Secondary cleavage is then performed in the cavity direction to thereby obtain a semiconductor laser device having a cavity structure. The resultant semiconductor laser device is packaged and routed.

The number of process steps may be reduced by forming the light absorption layers 17 in the following process. After the formation of the dielectric layer 16 on the semiconductor multilayer structure 12, openings are selectively formed on the top face of the ridge waveguide portion 12a and in the regions in which the light absorption layers 17 are to be formed. Thereafter, Pd and Pt are sequentially formed in the openings by electron beam evaporation and the like, to thereby form the p-side electrode 21 and the light absorption layers 17 simultaneously. The thicknesses of Pd and Pt may be 40 nm and 35 nm, respectively, for example. In place of the multilayer film of Pd and Pt, other materials may be used.

By employing the above process, in which the p-side electrode and the light absorption layers are formed simultaneously, the number of process steps can be reduced. When the distance d1 of the light absorption layers from the ridge center was set at 2 μm, the length d2 thereof in the cavity direction at 25 μm and the width d3 thereof in the end face direction at 50 μm in the case of using the multilayer film of Pd and Pt for the p-side electrode and the light absorption layers, the resultant leak light absorption effect was roughly identical to that obtained when the length d2 in the cavity direction was 10 μm in the case of using amorphous silicon.

### Embodiment 2

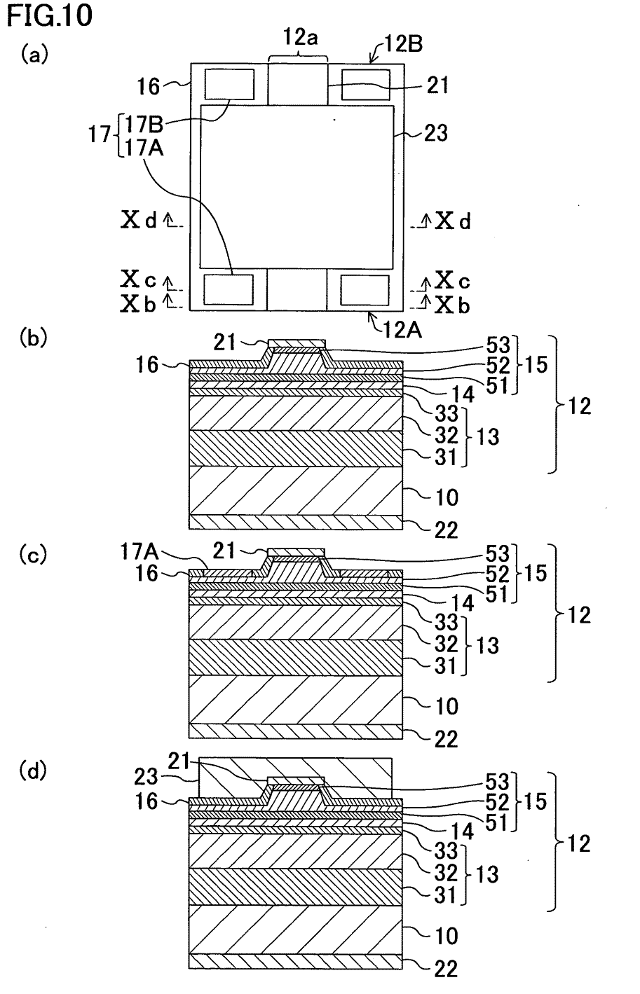

Embodiment 2 of the present invention will be described with reference to the relevant drawings. FIGS. 10(a) to 10(d) show a semiconductor laser device of Embodiment 2, wherein (a) shows a plan structure, and (b), (c) and (d) respectively show cross-sectional structures taken along line Xb-Xb, line Xc-Xc and line Xd-Xd in (a). In FIG. 10, the same components as those in FIG. 1 are denoted by the same reference numerals, and description thereof is omitted in this embodiment.

In the semiconductor laser device of this embodiment, each of the light absorption layers 17 has a first portion 17A formed near the light output end face 12A and a second portion 17B formed near the rear end face 12B.

The effect of absorbing leak light by the light absorption layer depends on the length of the light absorption layer in the cavity direction. Hence, by forming a light absorption layer also near the rear end face, the light absorption effect can be roughly doubled.

From the standpoint of the process for fabricating a semiconductor laser, it is preferred that the first portion 17A and the second portion 17B have the same shape and that the spacing between the first portion 17A and the light output end face is equal to the spacing between the second portion 17B and the rear end face. In other words, in the process for fabricating a semiconductor laser device, the first portion 17A and the second portion 17B are preferably symmetric with respect to the primary cleavage line.

Specifically, as shown in FIG. 11, in two laser cavities formed consecutively in the cavity direction on the substrate, the first portion 17A and the second portion 17B are formed to be axially symmetric with respect to a primary cleavage line 61. If there is a structure asymmetric with respect to a cleavage line, a cleavage failure such as cleavage deviation, a crack and a step are likely to occur. Such a cleavage failure causes deterioration of the FFP shape. By forming the first portion 17A and the second portion 17B symmetrically with respect to the primary cleavage line, therefore, occurrence of a cleavage failure can be reduced. This can not only improve the FFP shape but also improve the yield. In the resultant semiconductor laser device after the cleavage, the first portion 17A and the second portion 17B are axially symmetric with respect to the center line of the cavity structure in the end face direction.

To further facilitate the cleavage, cleavage guide grooves 62 may be formed as shown in FIG. 12. The cleavage guide grooves 62 may be of any shape, but correct guidance can be ensured if the top end thereof is V-shaped. Also, if the depth is as large as about 3 μm, reaching the n-type cladding layer 32 or the n-type GaN layer 31, cleavage can be correctly guided.

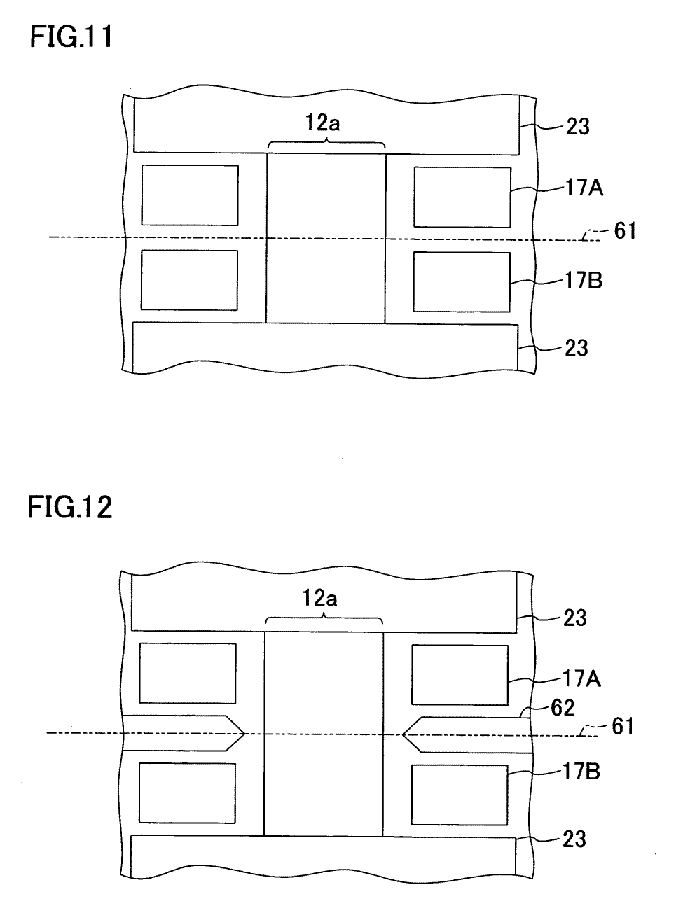

In the case of forming the cleavage guide grooves, steps 62a will be formed at the light output end face 12A and the rear end face 12B as marks of the cleavage guide grooves as shown in FIG. 13. Note that the cleavage guide grooves may also be formed in the case of Embodiment 1 in which the light absorption layers 17 are only formed near the light output end face 12A. In this case, also, cleavage failures can be reduced.

In this embodiment, also, the number of process steps can be reduced by forming the light absorption layers 17 and the p-side electrode 21 using the same materials.

### Embodiment 3

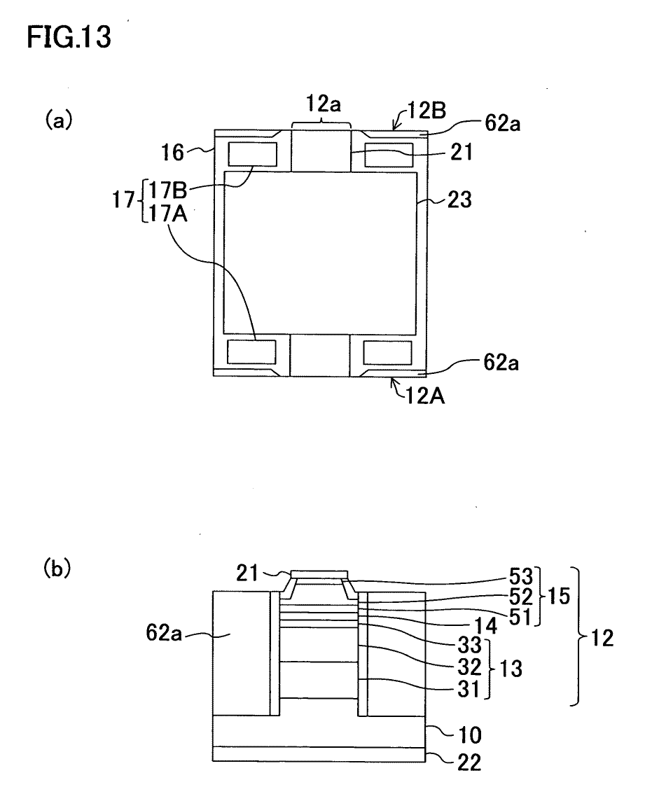

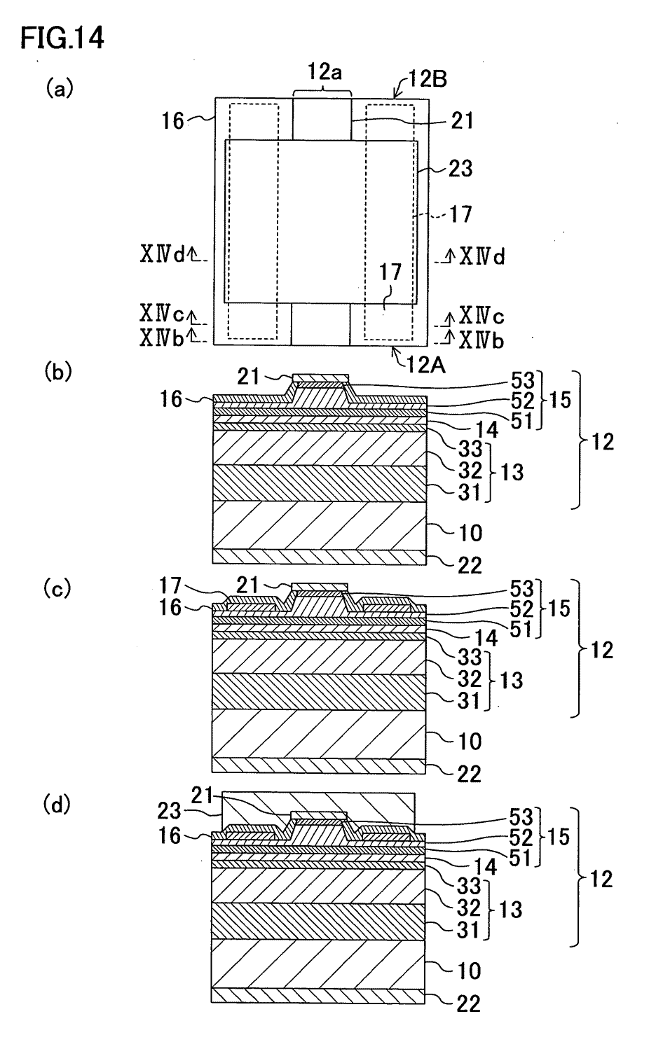

Embodiment 3 of the present invention will be described with reference to the relevant drawings. FIGS. 14(a) to 14(d) show a semiconductor laser device of Embodiment 3, wherein (a) shows a plan structure, and (b), (c) and (d) respectively show cross-sectional structures taken along line XIVb-XIVb, line XIVc-XIVc and line XIVd-XIVd in (a). In FIG. 14, the same components as those in FIG. 1 are denoted by the same reference numerals, and description thereof is omitted in this embodiment.

In the semiconductor laser device of this embodiment, the light absorption layers 17 are covered with the dielectric layer 16. Hence, the electrical insulation between the p-side electrode pad and the light absorption layers 17 can be secured even when the length of the light absorption layers 17 in the cavity direction is large. This permits formation of the light absorption layers 17 using a material small in effective absorption coefficient ae. For example, even with use of a material whose effective absorption coefficient αe is 100 cm⁻¹, the leak light intensity can be reduced to 1/10 or less by setting the length of the light absorption layers 17 in the cavity direction at 300 μm or more.

For a semiconductor laser device having a short cavity length, also, the light absorption layers can secure a large length in the cavity direction. For example, when the cavity length is 400 μm, a light absorption layer having a length of 390 μm in the cavity direction, i.e., the entire length excluding 5 μm each from both end faces, can be formed.

The semiconductor laser device of this embodiment may be fabricated in the following manner. The ridge waveguide portion 12a is formed as in Embodiment 1. Thereafter, the light absorption layers 17 made of amorphous silicon having a thickness of 200 nm are formed on both sides of the ridge waveguide portion 12a. Subsequently, a SiO₂ film having a thickness of 200 nm is formed on the entire surface of the substrate 10, and then a portion of the SiO₂ film formed on the ridge waveguide portion 12a is selectively etched, to thereby form the dielectric layer 16. The p-side electrode 21 is then formed on the ridge waveguide portion 12a. Subsequently, after formation of the p-side electrode pad 23, the n-side electrode 22 and the like, cleavage, formation of reflection films and the like are performed.

By following the above process, in which the light absorption layers are formed immediately after formation of the ridge waveguide portion 12a, insulation of the light absorption layers 17 from the p-side electrode 21 and the p-side electrode pad 23 can be secured with only the SiO₂ dielectric layer 16 for current narrowing and light trapping. Hence, light absorption layers with a higher leak light absorption effect can be formed with the same number of process steps as in Embodiment 1. With this configuration, a nitride semiconductor laser providing a more satisfactory FFP shape can be implemented. Note that in this embodiment, also, the cleavage guide grooves can be provided.

### Embodiment 4

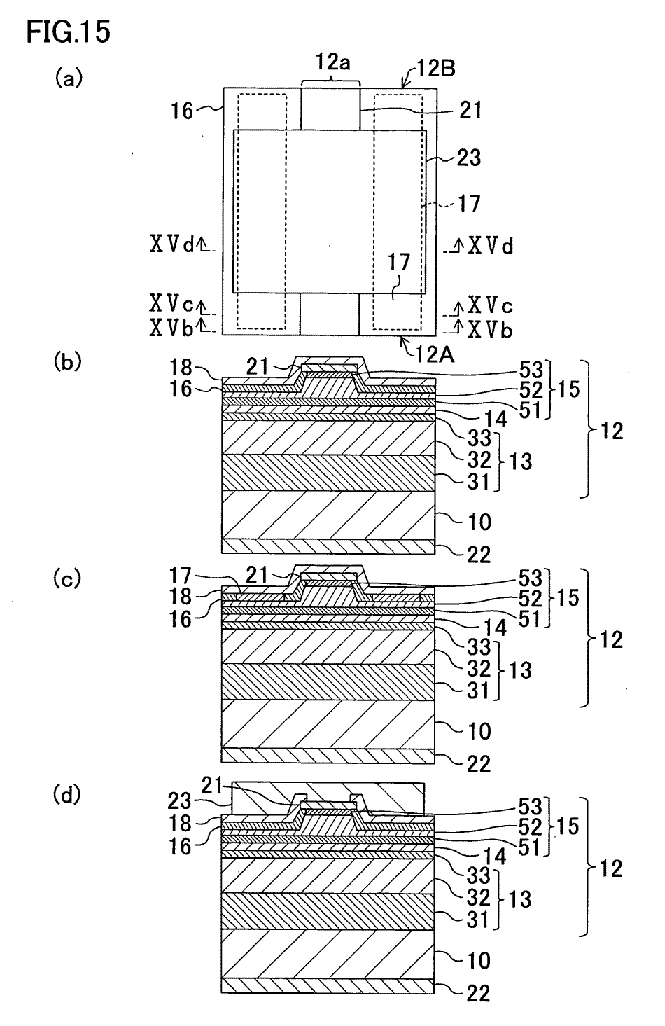

Embodiment 4 of the present invention will be described with reference to the relevant drawings. FIGS. 15(a) to 15(d) show a semiconductor laser device of Embodiment 4, wherein (a) shows a plan structure, and (b), (c) and (d) respectively show cross-sectional structures taken along line XVb-XVb, line XVc-XVc and line XVd-XVd in (a). In FIG. 15, the same components as those in FIG. 1 are denoted by the same reference numerals, and description thereof is omitted in this embodiment.

The semiconductor laser device of this embodiment includes an insulating layer 18 formed between the light absorption layers 17 and the p-side electrode pad 23. With placement of the insulating layer 18, the electrical insulation between the p-side electrode pad and the light absorption layers 17 can be secured even when the length of the light absorption layers 17 in the cavity direction is large. Also, with placement of the insulating layer 18, the light absorption layers 17 can be formed after the p-side electrode 21 is formed and heat-treated. This provides an additional effect of widening the range of selection of materials for the p-side electrode 21 and the light absorption layers 17.

The semiconductor laser device of this embodiment may be fabricated in the following manner. After formation of the p-side electrode 21 and the light absorption layers 17 as in Embodiment 1, the insulating film 18 made of SiO₂ having a thickness of 50 nm is formed on the entire surface of the substrate 10. Thereafter, an opening exposing the p-side electrode 21 is formed in the insulating film 18 by photolithography and wet etching with BHF. Subsequently, after formation of the p-side electrode pad 23, the n-side electrode 22 and the like, cleavage, formation of reflection films and the like are performed. The insulating layer 18 may be made of a material other than SiO₂. In this embodiment, also, the number of process steps can be reduced by forming the light absorption layers 17 and the p-side electrode 21 using the same materials. Also, cleavage guide grooves may be provided.

### INDUSTRIAL APPLICABILITY

According to the present invention, a nitride semiconductor laser device in which ripples are reduced and the far field pattern shape is close to a Gaussian shape can be implemented. Hence, the present invention is useful for a blue to ultraviolet semiconductor laser device using a nitride and a fabrication method for the same, and in particular for a nitride semiconductor laser device serving as a write and read light source for a high-density optical disc and a fabrication method for the same.

1. A semiconductor laser device provided with a cavity structure having a pair of cavity end faces opposed to each other, comprising:
a semiconductor multilayer structure including an n-type semiconductor layer, an active layer and a p-type semiconductor layer sequentially formed on a substrate in this order and having a stripe-shaped ridge waveguide portion extending in a direction intersecting the cavity end faces;
a dielectric layer formed on the semiconductor multilayer structure to cover at least part of both side faces of the ridge waveguide portion;
light absorption layers formed on both sides of the ridge waveguide portion on the semiconductor multilayer structure so as to be spaced from the ridge waveguide portion and the cavity end faces; and
a p-side electrode formed on the ridge waveguide portion.

2. The semiconductor laser device of claim 1, wherein the light absorption layers are conductive and electrically insulated from the p-side electrode.

3. The semiconductor laser device of claim 1, further comprising an insulating layer formed between the light absorption layers and the p-side electrode.

4. The semiconductor laser device of claim 1, wherein the light absorption layers are axially symmetric with respect to the ridge waveguide portion.

5. The semiconductor laser device of claim 1, wherein the light absorption layers are formed near a light output end face, out of the cavity end faces, from which light emerges.

6. The semiconductor laser device of claim 1, wherein each of the light absorption layers has a first portion formed near a light output end face from which light emerges and a second portion formed near a cavity end face opposite to the light output end face.

7. The semiconductor laser device of claim 6, wherein the spacing between the first portion and the light output end face is equal to the spacing between the second portion and the cavity end face opposite to the light output end face.

8. The semiconductor laser device of claim 7, wherein the first portion and the second portion are axially symmetric with respect to a center line of the cavity structure in an end face direction.

9. The semiconductor laser device of claim 1, wherein the semiconductor multilayer structure has a step portion formed at least at a region of the cavity end faces excluding the ridge waveguide portion.

10. The semiconductor laser device of claim 1, wherein the distance between the light absorption layers and the center of the ridge waveguide portion is 10 μm or less.

11. The semiconductor laser device of claim 1, wherein the length of the light absorption layers in a direction parallel to the ridge waveguide portion is 5 μm or more.

12. The semiconductor laser device of claim 1, wherein the light absorption layers are made of a material whose refractive index n and extinction coefficient k at an oscillating wavelength satisfy n≧1 and n+2k≧2.

13. The semiconductor laser device of claim 12, wherein the light absorption layers are made of a material whose refractive index n and extinction coefficient k at an oscillating wavelength satisfy n>2 and 0.001<k<2.5.

14. The semiconductor laser device of claim 1, wherein the light absorption layers include at least one of Cu, Pd, Zr, Nb, Cr, Ni, Au, Pt, Ti, Ta, W, Mo and amorphous Si.

15. The semiconductor laser device of claim 1, wherein the light absorption layers include at least one of CrN, TiN, ZrN, NbN, TaN and MoN.

16. The semiconductor laser device of claim 1, wherein the light absorption layers is include the same metal material as that included in the p-side electrode.

17. A fabrication method for a semiconductor laser device, comprising the steps of:
forming a semiconductor multilayer structure including an n-type semiconductor layer, an active layer and a p-type semiconductor layer on a substrate sequentially by crystal growth;
forming a ridge waveguide portion extending in a cavity direction in the p-type semiconductor layer;
forming a dielectric layer on the p-type semiconductor layer;
forming a first opening exposing the top face of the ridge waveguide portion in the dielectric layer and also forming a second opening exposing the p-type semiconductor layer in at least part of a region of the dielectric layer excluding the ridge waveguide portion and a portion becoming a cavity end face by cleavage; and
forming a p-side electrode and a light absorption layer by filling the first opening and the second opening with a metal material.
